(19) United States
(12) Patent Application Publication
(10) Pub. No.: US 2024/0253154 A1
(43) Pub. Date: Aug. 1, 2024

(54) LASER MACHINING APPARATUS, LASER MACHINING METHOD, AND DATA GENERATION METHOD

(71) Applicants: HAMAMATSU PHOTONICS K.K., Hamamatsu-shi, Shizuoka (JP); Tokyo Electron Limited, Minato-ku, Tokyo (JP)

(72) Inventors: Yo SUGIMOTO, Hamamatsu-shi, Shizuoka (JP); Yohei YAMASHITA, Ozu-Machi Kikuchi-gun, Kumamoto (JP)

(73) Assignees: HAMAMATSU PHOTONICS K.K., Hamamatsu-shi, Shizuoka (JP); Tokyo Electron Limited, Minato-ku, Tokyo (JP)

(21) Appl. No.: 18/289,269

(22) PCT Filed: Mar. 24, 2022
(86) PCT No.: PCT/JP2022/014172

§ 371 Date: Nov. 2, 2023

(30) Foreign Application Priority Data
May 14, 2021 (JP) 2021-082445

(51) Int. Cl. B23K 26/0622; B23K 26/03; B23K 31/12; B23K 101/40

(52) U.S. Cl. CPC B23K 26/0622; B23K 26/032; B23K 31/12; B23K 2101/40

(57) ABSTRACT

Provided is a laser processing apparatus configured to irradiate a substrate including a first main surface and a second main surface opposite to the first main surface with processing laser light. The laser processing apparatus includes: a processing irradiation unit configured to irradiate the substrate with the processing laser light from the second main surface side; an observation irradiation unit configured to irradiate the substrate with observation transmission light from the second main surface side; an imaging element configured to image the observation transmission light from the substrate; and a controller configured to execute a processing process of irradiating the substrate with the processing laser light by controlling the processing irradiation unit, and a characteristic acquisition process of irradiating the substrate with the observation transmission light, imaging the observation transmission light from the substrate.

### TECHNICAL FIELD

The present disclosure relates to a laser processing apparatus, a laser processing method, and a data generation method.

### BACKGROUND ART

Patent Literature 1 discloses a laser lift-off method as an example of the laser processing method. In the method, processing is performed on a target object constituted by joining an epi-wafer and a support substrate. The epi-wafer includes a sapphire substrate and a GaN-based epitaxial crystal layer formed on a first main surface of the sapphire substrate. As the support substrate, a support substrate obtained by forming an ohmic electrode having a stacked structure of Ti/Pt and a joining metal of Au/AuSn stacked from the ohmic electrode side with respect to a p-type silicon substrate can be used. The epi-wafer and the support substrate are joined with a joining metal layer interposed therebetween. In the method described in Patent Literature 1, laser light is emitted from a second main surface side opposite to the first main surface of the sapphire substrate. The laser light is condensed to a predetermined position inside the sapphire substrate and is moved (scanned) in a direction parallel to the first main surface to form a peeling interface. The laser light is preferably a pulse laser with a high peak output.

### CITATION LIST

### Patent Literature

Patent Literature 1: Japanese Unexamined Patent Publication No. 2011-040564

### SUMMARY OF INVENTION

### Technical Problem

By the way, peeling of a target object may be performed by forming a predetermined peeling interface as the laser lift-of or another laser light processing. In this case, in the processing apparatus, when the kind of an objective lens for condensing the laser light toward a target object, various specifications and settings such as a beam diameter of the laser light incident to the objective lens are changed, a processing threshold value (energy of the laser light) of the target object also changes. Accordingly, in a case of performing laser processing by using a plurality of processing apparatuses in parallel, there is a concern that a machine difference may occur in processing characteristics between the respective processing apparatuses. As described above, in the above-described technical field, there is a demand for suppressing the machine difference.

An object of the present disclosure is to provide a laser processing apparatus, a laser processing method, and a data generation method which are capable of suppressing a machine difference in processing characteristics.

### Solution to Problem

A laser processing apparatus according to the present disclosure is a laser processing apparatus configured to irradiate a substrate including a first main surface and a second main surface opposite to the first main surface with processing laser light. The laser processing apparatus includes: a processing irradiation unit configured to irradiate the substrate with the processing laser light from the second main surface side; an observation irradiation unit configured to irradiate the substrate with observation transmission light from the second main surface side; an imaging element configured to image the observation transmission light from the substrate; and a controller configured to execute a processing process of irradiating the substrate with the processing laser light by controlling the processing irradiation unit, a characteristic acquisition process of irradiating the substrate with the observation transmission light, imaging the observation transmission light from the substrate, and acquiring processing characteristics on the substrate in the processing process by controlling the observation irradiation unit and the imaging element, and an adjustment process of adjusting a pulse width of the processing laser light in correspondence with the processing characteristics. In the adjustment process, on the basis of reference data including a reference pulse width and reference processing characteristics associated with the reference pulse width, in a case where the processing characteristics acquired in the characteristic acquisition process do not match the reference processing characteristics, the controller adjusts the pulse width of the processing laser light so that the processing characteristics match the reference processing characteristics.

### Advantageous Effects of Invention

According to the present disclosure, a laser processing apparatus, a laser processing method, and a data generation method which are capable of suppressing a machine difference in processing characteristics can be provided.

### BRIEF DESCRIPTION OF DRAWINGS

FIG. 1 is a schematic view illustrating a laser processing apparatus according to an embodiment.

FIG. 2 is a schematic view illustrating a laser processing target object in the laser processing apparatus illustrated in FIG. 1.

FIG. 3 is a flowchart illustrating an example of a laser processing method using the laser processing apparatus illustrated in FIG. 1.

FIG. 4 is a schematic view illustrating a process in the laser processing method illustrated in FIG. 3.

FIG. 5 is a table showing processing characteristics (processing results) in a case of performing peeling processing by a plurality of the laser processing apparatuses.

FIG. 6 is a schematic view illustrating a state when viewing a functional element layer after processing from a Z-direction.

FIG. 7 is a flowchart illustrating an example of a laser processing method according to an embodiment.

FIG. 8 is a graph illustrating a pulse waveform.

FIG. 9 is a view illustrating a process of the laser processing method according to an embodiment.

FIG. 10 is a table showing a pulse width adjustment result.

FIG. 11 is a schematic view illustrating a laser processing apparatus according to a first modification example.

FIG. 12 is a schematic view illustrating a laser processing apparatus according to a second modification example.

FIG. 13 is a schematic view illustrating a modification example of an observation head according to the second modification example.

FIG. 14 is a schematic view illustrating a laser processing apparatus according to a third modification example.

FIG. 15(a) is a plan view and a cross-sectional view of a target object for describing a first example of forming a modified region at a partial region of a functional element layer, and FIG. 15(b) is a plan view and a cross-sectional view of a target object for describing a second example of forming a modified region at a partial region of the functional element layer.

FIG. 16(a) is a plan view and a cross-sectional view of a target object for describing a third example of forming a modified region at a partial region of the functional element layer, and FIG. 16(b) is a plan view and a cross-sectional view of a target object for describing a fourth example of forming the modified region at a partial region of the functional element layer.

### DESCRIPTION OF EMBODIMENTS

Hereinafter, an embodiment will be described in detail with reference to the accompanying drawings. Note that, in the respective drawings, the same reference numeral will be given to the same or equivalent portion, and redundant description thereof may be omitted.

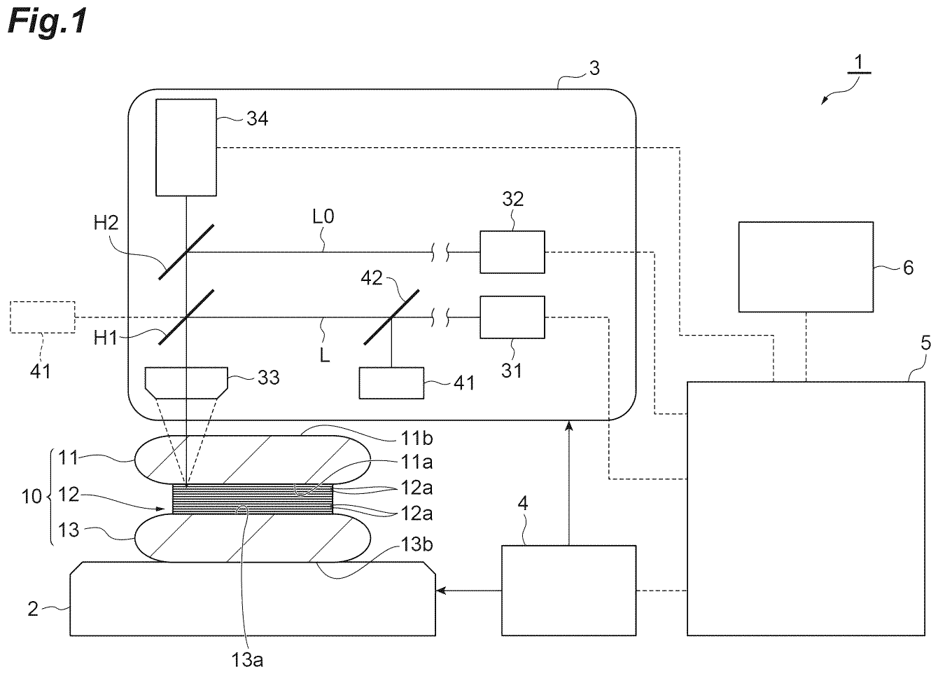

As illustrated in FIG. 1, a laser processing apparatus 1 is an apparatus configured to form a modified region in a substrate 10 by irradiating the substrate 10 with laser light (processing laser light) L. Note that, in the following description, three directions orthogonal to each other may be referred to as an X-direction, a Y-direction, and a Z-direction. As an example, the X-direction is a first horizontal direction, the Y-direction is a second horizontal direction orthogonal to the first horizontal direction, and the Z-direction is a vertical direction and is a thickness direction of the substrate 10.

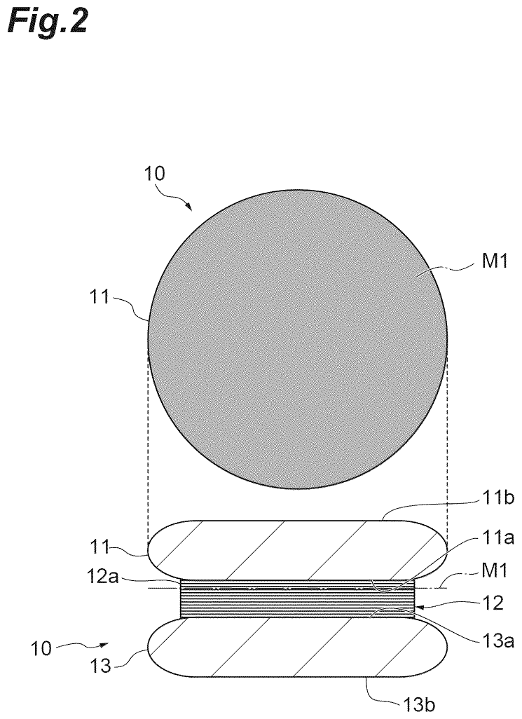

As illustrated in FIG. 2, the substrate 10 includes a first substrate 11, a functional element layer 12, and a second substrate 13. The first substrate 11, the functional element layer 12, and the second substrate 13 are disposed to be stacked in this order along the Z-direction. For example, the first substrate 11 and the second substrate 13 are wafers formed in a disk shape. As an example, the first substrate 11 and the second substrate 13 are semiconductor substrates such as a silicon substrate, piezoelectric material substrates formed from a piezoelectric material, glass substrates formed from glass, and the like.

A notch or an orientation flat indicating a crystal direction may be provided in the first substrate 11 and the second substrate 13. The first substrate 11 includes a front surface (first main surface) 11a and a rear surface (second main surface) 11b opposite to the front surface 11a. The second substrate 13 includes a front surface 13a and a rear surface 13b opposite to the front surface 13a. The first substrate 11 and the second substrate 13 are disposed so that the front surfaces 11a and 13a thereof face each other.

The functional element layer 12 is provided on the front surface 11a side of the first substrate 11. The functional element layer 12 is provided on the front surface 13a side of the second substrate 13. That is, the functional element layer 12 is interposed between the first substrate 11 and the second substrate 13. The functional element layer 12 includes a plurality of functional elements. Examples of the functional elements include a wiring element, a light-receiving element such as a photodiode, a light-emitting element such as a laser diode, a circuit element such as a memory, and the like. In a case of being three-dimensionally constituted by stacking a plurality of layers 12a, the functional elements may be arranged in a matrix shape.

For example, the plurality of layers 12a constituting the functional element layer 12 may include a plurality of metal layers and a plurality of non-metal layers stacked along the Z-direction. Examples of the metal layers include a titanium (Ti) layer, and a tin (Sn) layer. Examples of the non-metal layers include an oxide film layer, and a nitride film layer. As an example, the non-metal layer can include an oxide film layer including a silicon oxide film such as silicon monoxide (SiO), and a layer such as silicon carbon nitride (SiCN). For example, the metal layers and the non-metal layers can be formed on the front surfaces 11a and 13a by a film forming treatment (sputtering, evaporation, and/or CVD, and the like), etching (dry etching, and/or wet etching), polishing, and the like.

A virtual plane M1 is set in the substrate 10 as a plane to be peeled. The virtual plane M1 is a plane in which formation of a modified region is planned. The virtual plane M1 is a plane that faces the rear surface 11b that is an incident surface of laser light L in the substrate 10. The virtual plane M1 is a plane parallel to the rear surface 11b, and shows, for example, a circular shape. The virtual plane M1 is a virtual region, and may be a curved plane or a three-dimensional plane without limitation to a flat plane. For example, setting of the virtual plane M1 may be performed by a user through an input unit. The virtual plane M1 may be coordinate-specified.

The laser processing apparatus 1 irradiates the substrate 10 with the laser light L in conformity to focusing points (at least a part of a condensing region) to form the modified region inside the functional element layer 12 of the substrate 10 along the virtual plane M1. The laser processing apparatus 1 performs laser processing including peeling processing with respect to the substrate 10. The peeling processing is processing for peeling a part of the substrate 10. The laser processing apparatus 1 has a function as a laser bonding apparatus.

The laser processing apparatus 1 includes a support portion 2, a laser processing head (processing irradiation unit, observation irradiation unit) 3, a movement mechanism 4, a controller 5, and a display unit 6. The support portion 2 supports the substrate 10, for example, by suction or the like. The support portion 2 is movable along each of the X-direction, the Y-direction, and the Z-direction. The substrate 10 is supported by the support portion 2 so that the rear surface 11b becomes the laser processing head 3 side. The support portion 2 is rotatable around a rotational axis along the Z-direction.

The laser processing head 3 includes a processing light source 31, an observation light source 32, a condensing unit 33, a first imaging element 34, a pulse waveform sensor 41, and a mirror 42. For example, the processing light source 31 emits the processing laser light L by pulse oscillation method. The laser light L is laser light in a wavelength region absorbable to the functional element layer 12. As the processing light source 31, for example, a solid pulse laser device can be used, a wavelength of the laser light L is a wavelength having a transmitting property with respect to the first substrate 11, and is, for example, 355 nm in a case where the first substrate 11 is formed from sapphire or glass. The observation light source 32 emits observation transmission light L0. The observation transmission light L0 is light in a wavelength region having a transmitting property with respect to the first substrate 11. As the observation light source 32, various light sources capable of emitting the observation transmission light L0 can be used without particular limitation.

The condensing unit 33 condenses the laser light L and the observation transmission light L0 toward the substrate 10 supported by the support portion 2. Here, the laser light L emitted from the processing light source 31 is reflected from a dichroic mirror H1, and is incident to the condensing unit 33. In addition, the observation transmission light L0 emitted from the observation light source 32 is reflected from a dichroic mirror H2, is transmitted through the dichroic mirror H1, and is incident to the condensing unit 33. The condensing unit 33 condenses the incident laser light L and the incident observation transmission light L0 toward the substrate 10.

For example, the condensing unit 33 is configured to include a lens unit constituted by a plurality of condensing lenses (however, may be a single lens). As the lens unit of the condensing unit 33, for example, a lens unit with a low numerical aperture (NA) can be used. Note that, the condensing unit 33 may include a driving mechanism such as a piezoelectric element that drives the lens unit along the Z-direction. For example, 0.1 to 0.6 may be exemplified as the low NA.

The first imaging element 34 is an imaging element having sensitivity for the observation transmission light L0. The first imaging element 34 images the observation transmission light L0 from the substrate 10 (the functional element layer 12). More specifically, the first imaging element 34 receives reflected light corresponding to irradiation with the observation transmission light L0 (condensing of the observation transmission light L0 to the substrate 10 by the condensing unit 33). Here, reflected light of the observation transmission light L0 that is emitted to the substrate 10 and is reflected from the functional element layer 12 is detected (imaged) by the first imaging element 34 through the condensing unit 33 and the dichroic mirrors H1 and H2. According to this, the first imaging element 34 acquires an image of the functional element layer 12 by the observation transmission light L0. The first imaging element 34 outputs an acquired image to the controller 5.

In addition, the first imaging element 34 has sensitivity for the laser light L. The first imaging element 34 receives reflected light corresponding to irradiation with the laser light L (condensing of the laser light L to the substrate 10 by the condensing unit 33). Here, reflected light of the laser light L that is emitted to the substrate 10 and is reflected from the substrate 10 is detected (imaged) by the first imaging element 34 through the condensing unit 33 and the dichroic mirrors H1 and H2. According to this, the first imaging element 34 acquires an image related to a beam shape of the laser light L. The first imaging element 34 outputs information related to the obtained image to the controller 5.

The mirror 42 branches a part of the laser light L directed toward the condensing unit 33 from the processing light source 31. The pulse waveform sensor 41 receives incidence of the part of the laser light L branched by the mirror 42 to acquire a pulse waveform of the laser light L. The pulse waveform sensor 41 outputs information related to the obtained pulse waveform to the controller 5. As the pulse waveform sensor 41, for example, a photodiode type or an auto-correlator type can be used. Note that, the pulse waveform sensor 41 may be configured to receive incidence of a part of the laser light L which is transmitted from the dichroic mirror H1. In this case, the mirror 42 is not necessary.

The laser processing head 3 described above is configured to coaxially emit the laser light L and the observation transmission light L0. Accordingly, the laser processing head 3 constitutes a processing irradiation unit that irradiates the functional element layer 12 with the processing laser light L from the rear surface 11b side and an observation irradiation unit that irradiates the functional element layer 12 with the observation transmission light L0 transmitted through the first substrate 11 from the rear surface 11b side. The laser processing head 3 may be provided with a spatial light modulator configured to modulate the laser light L.

The movement mechanism 4 includes a mechanism that moves at least one of the support portion 2 and the laser processing head 3 along the X-direction, the Y-direction, and the Z-direction. The movement mechanism 4 can drive at least one of the support portion 2 and the laser processing head 3 by a driving force of a known driving device such as a motor so that a focusing point of the laser light L moves along the X-direction, the Y-direction, and the Z-direction. The movement mechanism 4 can drive at least one of the support portion 2 and the laser processing head 3 by a driving force of a known driving device such as a motor so that a focusing point (focal point) of the observation transmission light L0 moves along the Z-direction. Furthermore, the movement mechanism 4 can perform rotary drive to the support portion 2 by a driving force of a known driving device such as a motor so that the focusing point of the laser light L moves along a θ-direction around a rotary axis.

The controller 5 controls operations of respective portions of the laser processing apparatus 1. The controller 5 is constituted by a computer device including a processor, a memory, a storage, a communication device, and the like. In the controller 5, the processor executes software (program) read into the memory or the like, and controls reading-out and writing of data in the memory and the storage, and communication by the communication device. According to this, the controller 5 can execute the following processes.

Examples of the display unit 6 include a monitor and the like. The display unit 6 is controlled by the controller 5 and displays information (for example, imaging results) transmitted from the first imaging element 34. More specifically, the display unit 6 can display an image of the functional element layer 12 obtained by the observation transmission light L0. In addition, the display unit 6 can display information indicating a beam shape and a pulse width of the laser light L. As the display unit 6, various known display devices can be used without particular limitation.

Subsequently, an example of a laser processing method carried out by the laser processing apparatus 1 will be described. Here, description will be given of an example of peeling process of peeling the substrate 10 in the functional element layer 12 by using the laser processing apparatus 1.

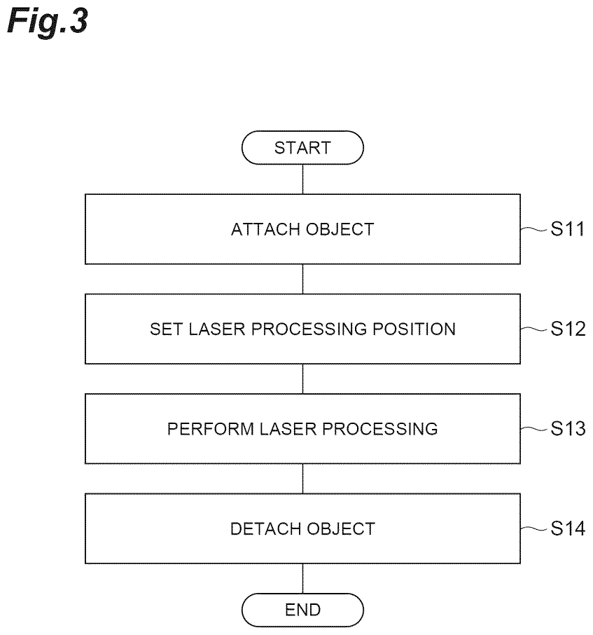

As illustrated in FIG. 3, in the method, first, the substrate 10 is attached to the support portion 2, and the substrate 10 is supported by the support portion 2 (process S11). In process S11, since the rear surface 11b of the first substrate 11 is set as an incident surface of the laser light L, the substrate 10 is supported on the support portion 2 so that the rear surface 11b faces the laser processing head 3 side. Next, a laser processing position is set (process S12). Here, as the laser processing position, a position of a focusing point of the laser light L related to the Z-direction that is the thickness direction (direction intersecting the front surface 11a and the rear surface 11b) of the substrate 10 is set.

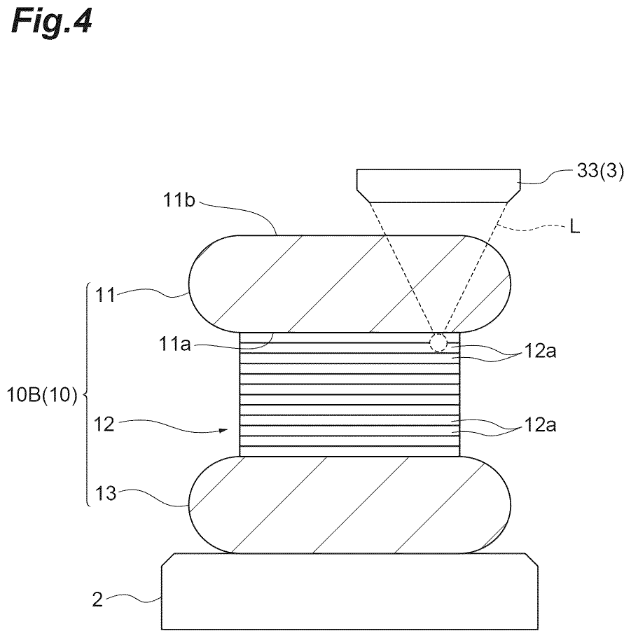

Next, as illustrated in FIG. 4, laser processing is performed (process S13). In process S13, the substrate 10 is irradiated with the laser light L by the laser processing head 3 from the rear surface 11b side of the first substrate 11. More specifically, the controller 5 controls the movement mechanism 4 to move the laser processing head 3 along the Z-direction so that a focusing point of the laser light L is located at the laser processing position set in process S12. In the state, the controller 5 controls the laser processing head 3 to irradiate the substrate 10 with the laser light L, and to condense the laser light L to the functional element layer 12.

In combination with the process, the controller 5 controls the movement mechanism 4 to move the laser processing head 3 in the X-direction and/or the Y-direction while rotating the support portion 2, and to move the focusing point of the laser light L along the virtual plane M1. According to this, a modified region is formed inside the functional element layer 12 along the virtual plane M1. Here, the modified region is formed to extend over the entirety of the functional element layer 12 when viewed from the Z-direction. Then, the substrate 10 is detached from the support portion 2 (process S14). Through the above processes, the peeling processing is terminated.

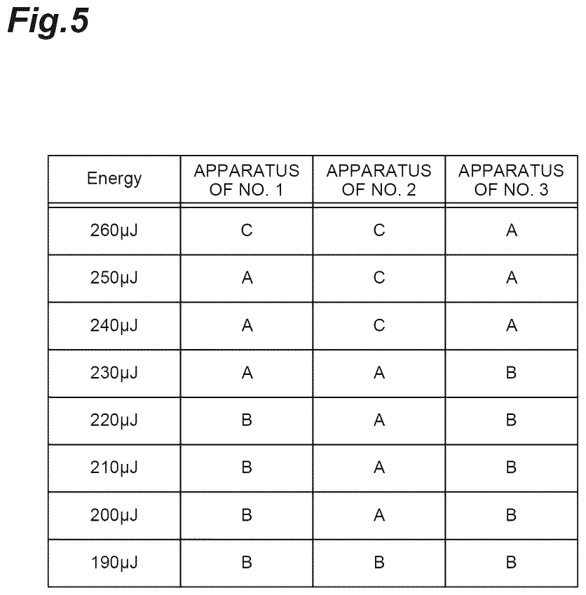

Here, the finding of the present invention about problems in the peeling processing will be described. In FIG. 5, an example in which the peeling processing is performed by using three laser processing apparatuses 1 of No. 1, No. 2, and No. 3 is shown.

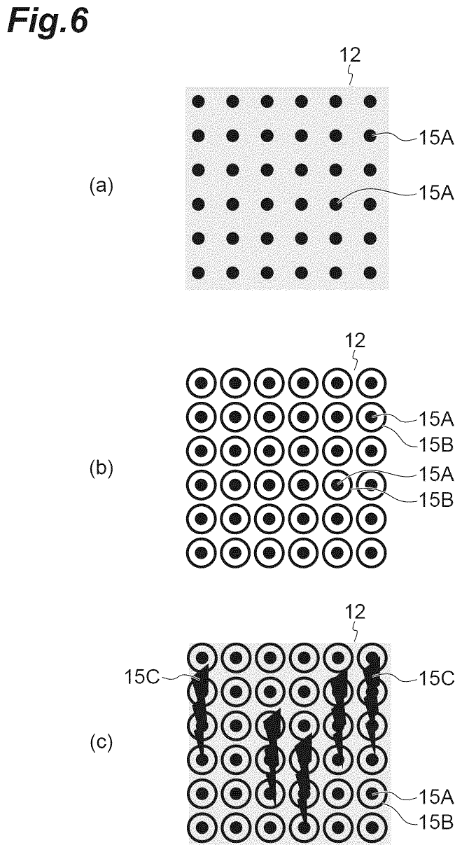

“B” in the table of FIG. 5 shows a processing result in which a modified region 15A is formed in the functional element layer 12, but a peeling portion is not generated at the periphery of the modified region 15A as illustrated in FIG. 6(a). “A” in the table of FIG. 5 shows a processing result in which the modified region 15A is formed in the functional element layer 12, and a peeling portion 15B is generated at the periphery of the modified region 15A as illustrated in FIG. 6(b). Furthermore, “C” in the table of FIG. 5 shows a processing result in which the modified region 15A and the peeling portion 15B are formed in the functional element layer 12, but a damage 15C is generated as illustrated in FIG. 6(c). A processing result preferable for the peeling processing is “A”.

As illustrated in FIG. 5, in the apparatus of No. 1, the preferable processing result “A” can be obtained in a case where energy of the laser light L is 230 μJ to 250 μJ. In the apparatus of No. 2, the preferable processing result “A” can be obtained in a case where the energy of the laser light L is 200 μJ to 230 μJ. In the apparatus of No. 3, the preferable processing result “A” can be obtained in a case where the energy of the laser light L is 240 μJ to 260 μJ. As described above, it is understood that a machine difference in processing characteristics occurs between the apparatuses of No. 1 to No. 3.

It is considered that the machine difference occurs because various specifications or settings such as the kind of an objective lens for condensing the laser light L toward the substrate 10, a beam diameter of the laser light L incident to the objective lens are different between the apparatus of No. 1 to the apparatus of No. 3. Accordingly, in the peeling processing, it is preferable to obtain uniform processing characteristics regardless of the specifications or settings of the laser processing apparatus 1 by suppressing the machine difference. Here, in the laser processing apparatus 1, the following laser processing method is carried out so as to suppress the machine difference.

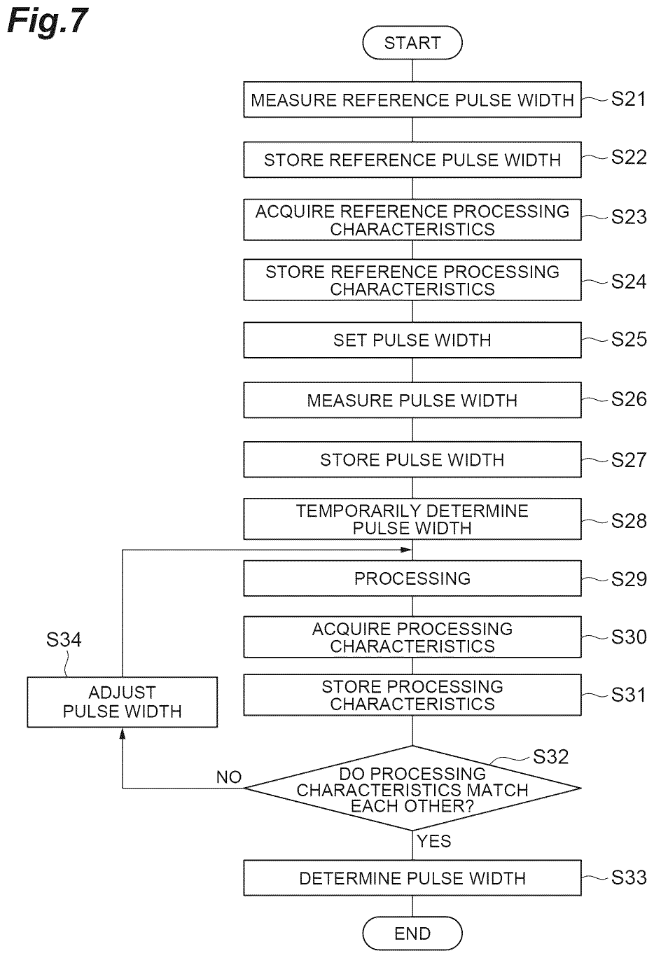

The following laser processing method includes a data creation method for creating reference data. As illustrated in FIG. 7, in the method, first, a reference pulse width is measured (process S21). The reference pulse width is an actual measurement value of a pulse width of the laser light L from the laser processing head 3 of one laser processing apparatus 1 being the reference (hereinafter, may be referred to as “reference processing apparatus”) among a plurality of the laser processing apparatuses 1. The reference processing apparatus may be, for example, one apparatus (for example, the apparatus of No. 1) among the apparatus of No. 1 to the apparatus of No. 3.

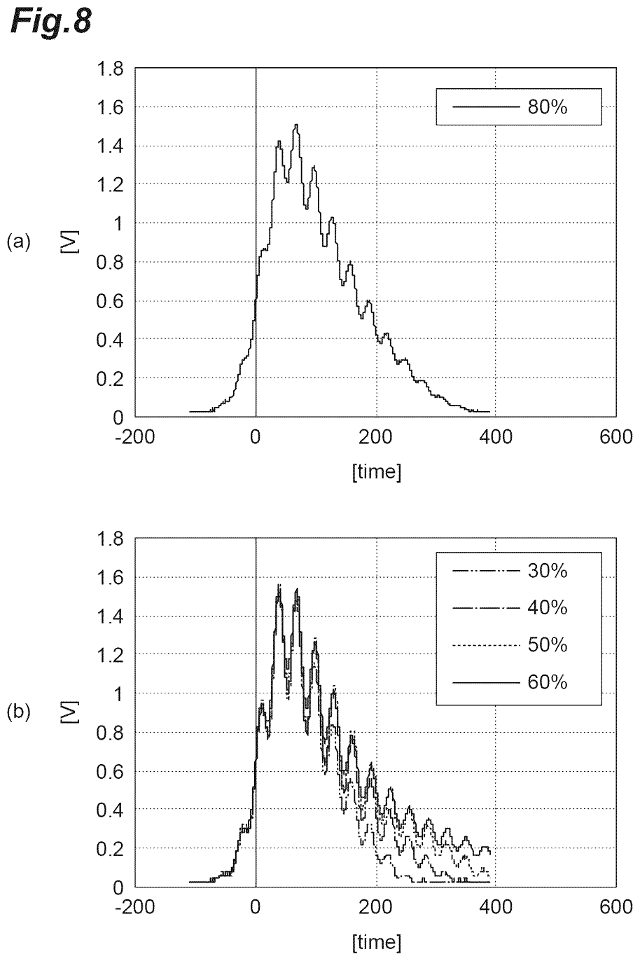

In process S21, the controller 5 controls the processing light source 31 of the reference processing apparatus to emit the laser light L from the processing light source 31. In combination with the process, in process S21, the controller 5 controls the pulse waveform sensor 41 of the reference processing apparatus to acquire a pulse waveform of the laser light L illustrated in FIG. 8(a). Then, the controller 5 acquires the pulse width (actual measurement value) of the laser light L on the basis of the obtained pulse waveform. The actual measurement value of the pulse width acquired here is the reference pulse width. The pulse width may be a half-width of the pulse waveform. However, here, the pulse width is a full width of the pulse waveform between 0 V and 0 V. In addition, with regard to a setting value of the pulse width for outputting the acquired pulse width (actual measurement value), as an example, in a case where a lower limit of a settable range of the pulse width is set to 0%, and an upper limit thereof is set to 100%, the upper limit is set to 80%. The controller 5 stores the acquired pulse width (process S22).

Next, reference processing characteristics are acquired (process S23). More specifically, here, first, the substrate 10 (hereinafter, may be referred to as “reference target object”) is set to a state of being supported by the support portion 2. In this state, the controller 5 of the reference processing apparatus controls the processing light source 31 (processing irradiation unit) of the reference processing apparatus to emit the laser light L from the processing light source 31. According to this, a reference layer that is the functional element layer 12 of the reference target object is irradiated with the laser light L from the rear surface 11b side to form a modified region in the reference layer (reference processing process).

Then, in process S23, the controller 5 controls the observation light source 32 (observation irradiation unit) to emit the observation transmission light L0 from the observation light source 32. According to this, the reference layer is irradiated with the observation transmission light L0 from the rear surface 11b side. In combination with this process, the controller 5 controls the first imaging element 34 to image the observation transmission light L0 (reflected light) from the reference layer. According to this, the reference processing characteristics which are processing characteristics of the reference layer are acquired (reference characteristic acquisition process). For example, the reference processing characteristics are images of the reference layer after processing. Then, the controller 5 stores the acquired reference processing characteristics (process S24). The controller 5 stores the reference processing characteristics in association with the reference pulse width.

At this time, the controller 5 executes process S23 and process S24 a plurality of times while changing the pulse energy and constantly maintaining the pulse width of the processing laser light L. According to this, reference processing characteristics at a plurality of kinds of pulse energy can be acquired. According to this, for example, a series of reference processing characteristics shown in a column of one laser processing apparatus 1 (for example, the apparatus of No. 1) in the table of FIG. 5 can be obtained. Among the obtained reference processing characteristics, a processing characteristic with the lowest energy capable of obtaining the preferable processing result “A” becomes a processing threshold value.

As described above, the controller 5 associates the reference processing characteristics obtained in the characteristic acquisition process with the actual measurement value of the pulse width of the processing laser light L when obtaining the reference processing characteristics as the reference pulse width to generate reference data including the reference processing characteristics and the reference pulse width associated with the reference processing characteristics (generation process). Particularly, the reference data includes a reference image that is an image of the functional element layer 12 (reference layer) in a state in which the modified region 15A is formed as the reference processing characteristics.

The above-described method is a data generation method executed by the laser processing apparatus 1. Note that, the generated reference data may be retained by only the controller 5 of the reference processing apparatus. Alternatively, the generated reference data may be provided to controllers 5 of other laser processing apparatuses 1 and may be retained by the respective controllers 5. Furthermore, the generated reference data may be retained by an additional storage device that the controllers 5 of the plurality of laser processing apparatuses 1 can access through a network. That is, the reference data can be retained by any storage device that the controller 5 of the following adjustment target processing apparatus can access. In addition, the reference processing apparatus may be installed in an environment different from that of the adjustment target processing apparatus.

Subsequently, adjustment of a pulse width of a laser processing apparatus 1 different from the reference processing apparatus among the plurality of laser processing apparatuses 1 is performed. Hereinafter, the laser processing apparatus 1 that becomes a pulse width adjustment target may be referred to as “adjustment target processing apparatus”. The adjustment target processing apparatus is the apparatus of No. 2 or the apparatus of No. 3 as an example.

Here, first, the controller 5 of the adjustment target processing apparatus controls the processing light source 31 (processing irradiation unit) of the adjustment target processing apparatus to set the pulse width of the laser light L in the processing light source 31 to a predetermined setting value (process S25). Here, the controller 5 may automatically adjust the pulse width of the laser light L to a predetermined setting value. Alternatively, the controller 5 may cause the display unit 6 to display information for promoting an input of the setting value of the pulse width, and may set the pulse width to a value input to the display unit 6 on the basis of the information. In this manner, the display unit 6 is a display unit for displaying an image and is also an input reception unit for receiving an input.

Next, the controller 5 acquires an actual measurement value of the pulse width of the laser light L by measuring the pulse width (process S26). More specifically, in process S26, first, the controller 5 controls the processing light source 31 to emit the laser light L from the processing light source 31. In combination with the process, the controller 5 controls the pulse waveform sensor 41 of the adjustment target processing apparatus to acquire a pulse waveform of the laser light L illustrated in FIG. 8(b). Then, the controller 5 acquires the pulse width (actual measurement value) of the laser light L on the basis of the obtained pulse waveform.

The controller 5 performs a plurality of times of emission of the laser light L and acquisition of the pulse waveform while changing the setting value of the pulse width of the laser light L. According to this, the controller 5 acquires a combination of a plurality of the setting values of the pulse width and the actual measurement value. In an example illustrated in FIG. 8(b), as an example, in a case where a lower limit of a settable range of the pulse width is set to 0% and an upper limit thereof is set to 100%, the setting value is changed for every 10% in a range of the upper limit from 30% to 60%.

As described above, in process S26, the controller 5 executes the pulse width acquisition process of acquiring the setting value of the pulse width of the laser light L and the actual measurement value of the pulse width of the laser light L at the setting value by acquiring the pulse waveform by detecting the processing laser light L emitted from the processing light source 31 with the pulse waveform sensor a plurality of times while changing the setting value. According to this, the controller 5 acquires a plurality of the actual measurement values respectively associated with a plurality of the setting values of the pulse width of the laser light L. Then, the controller 5 stores the obtained setting values of the pulse width and the obtained actual measurement values (process S27).

In a subsequent process, the controller 5 temporarily determines the pulse width (process S28). More specifically, in process S28, the controller 5 determines (temporarily determines) a setting value that becomes an actual measurement value closest to the reference pulse width acquired and stored in process S21 and process S22 among the plurality of actual measurement values acquired and stored in process S26 and process S27 as a temporal determination value on the basis of the reference data. As an example, the controller 5 can automatically perform acquisition of a temporal setting value that becomes the actual measurement value closest to the reference pulse width among the plurality of actual measurement values of the pulse width. In the example in FIG. 8(b), the actual measurement value closest to the reference pulse width (actual measurement value) was an actual measurement value output at a setting value of 40%. Accordingly, here, 40% is determined as the temporal setting value. Note that, hereinafter, notation of “temporal setting value of 40% at which a pulse width closest to the reference pulse width is output” is omitted, and is simply noted as “40%” or the like.

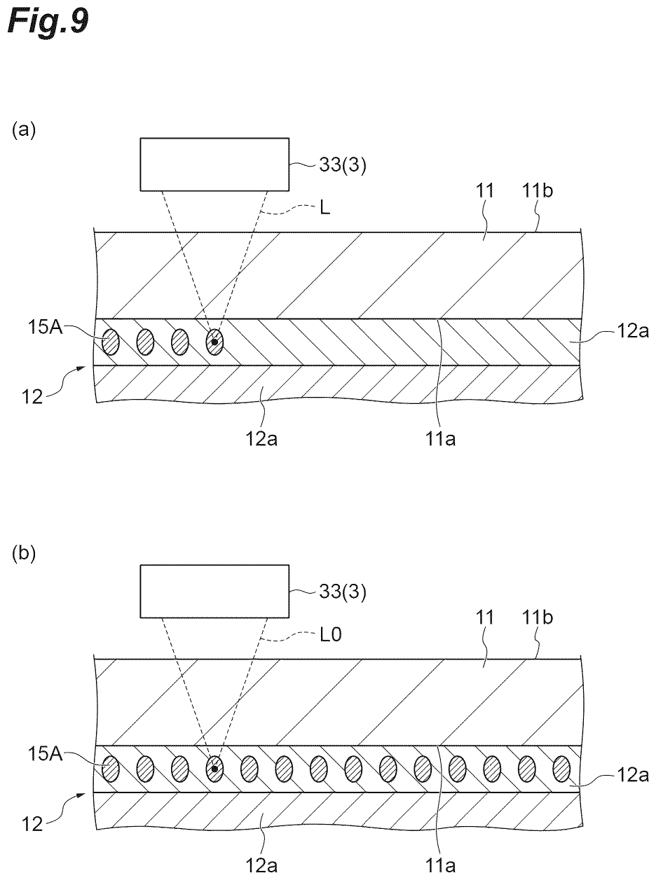

Next, laser processing is actually performed (process S29). More specifically, here, first, the substrate 10 is set to a state of being supported by the support portion 2 of the adjustment target processing apparatus. In the state, the controller 5 controls the movement mechanism 4 of the adjustment target processing apparatus to move the laser processing head 3 of the adjustment target processing apparatus along the Z-direction so that the focusing point of the laser light L is located at the laser processing position set in process S12. In this state, as illustrated in FIG. 9(a), the controller 5 controls the laser processing head 3 (processing irradiation unit) to irradiate the substrate 10 with the laser light L from the rear surface 11b side, and to condense the laser light L to the functional element layer 12. At this time, the pulse width of the laser light L is set to the temporal setting value determined in process S28.

In combination with the process, the controller 5 controls the movement mechanism 4 to move the laser processing head 3 along the X-direction and/or the Y-direction while rotating the support portion 2, and to move the focusing point of the laser light L along the virtual plane M1. According to this, the modified region 15A is formed inside the functional element layer 12 along the virtual plane M1 (furthermore, the peeling portion 15B and the damage 15C may be formed).

That is, in process S29, the controller 5 controls the laser processing head 3 (processing irradiation unit) and the movement mechanism 4 to execute a processing process of irradiating the functional element layer 12 with the processing laser light L and forming the modified region 15A in the functional element layer 12 along the virtual plane M1. At this time, the controller 5 sets the setting value of the pulse width of the laser light L to the above-described temporal setting value.

In the subsequent process, acquisition of processing characteristics is performed (process S30). More specifically, the controller 5 controls the movement mechanism 4 to move the laser processing head 3 of the adjustment target processing apparatus along the Z-direction so that the laser processing position (position in the Z-direction at which the modified region 15A is formed in the functional element layer 12) is irradiated with the observation transmission light L0. In this state, as illustrated in FIG. 9(b), the controller 5 controls the laser processing head 3 (observation irradiation unit) to irradiate the substrate 10 with the observation transmission light L0 from the rear surface 11b side.

In combination with the process, the controller 5 controls the first imaging element 34 to image the observation transmission light L0 (reflected light from the functional element layer 12). According to this, the controller 5 acquires an image of the functional element layer 12 processed through irradiation with the laser light L in process S29 as processing characteristics. Then, the controller 5 stores the acquired processing characteristics (process S31).

As described above, the controller 5 controls the laser processing head 3 and the first imaging element 34 to execute a characteristic acquisition process of irradiating the functional element layer 12 with the observation transmission light L0, imaging the observation transmission light L0 from the functional element layer 12, and acquiring processing characteristics of the functional element layer 12 in the processing process. Particularly, in the characteristic acquisition process, the controller 5 images the functional element layer 12 in a state in which the modified region 15A is formed by using the observation transmission light L0 to acquire a processing image that is an image of the functional element layer 12 as processing characteristics.

At this time, the controller 5 can acquire processing characteristics with a plurality of pulse energy by executing process S29 to process S31 a plurality of times while changing the pulse energy of the processing laser light L (while constantly maintaining the pulse width). According to this, for example, a series of processing characteristics as shown in a column of a laser processing apparatus 1 (for example, the apparatus of No. 2) different from the reference processing apparatus in the table of FIG. 5 are obtained. Among the obtained processing characteristics, the lowest pulse energy capable of obtaining the preferable processing result “A” becomes a processing threshold value here.

In the subsequent process, determination is made as to whether or not the processing characteristics acquired in process S30 match the reference processing characteristics (process S32). Here, as an example, the determination can be automatically performed by the controller 5. In this case, first, the controller 5 performs image recognition of a reference image as the reference processing characteristics included in the reference data to determine that each of a plurality of the reference images obtained with different pulse energy pertains to which processing result among “A”, “B”, and “C”. Then, the controller 5 recognizes the lowest pulse energy capable of obtaining a reference image determined as “A” as processing threshold value (reference processing threshold value) of the reference processing apparatus.

On the other hand, the controller 5 performs image recognition of an image as the processing characteristics acquired in process S30 to determine that each of a plurality of processing images obtained with different pulse energy pertains to which processing result among “A”, “B”, and “C”. Then, the controller 5 recognizes the lowest pulse energy capable of obtaining an image determined as “A” as a processing threshold value of the adjustment processing apparatus. Then, the controller 5 performs determination as to whether or not the reference processing threshold value that is the processing threshold value of the reference processing apparatus and the processing threshold value of the adjustment processing apparatus match each other. In this manner, the controller 5 compares the reference image (reference processing threshold value) and the processing image (processing threshold value) by the adjustment target processing apparatus through the image processing to determine whether or not the reference image and the processing image match each other.

From the determination result, in a case where the processing threshold value of the adjustment processing apparatus is included in a predetermined range (for example, reference processing threshold value ±5 μJ) including the reference processing threshold value, the controller 5 can determine that the reference processing threshold value and the processing threshold value of the adjustment processing apparatus match each other, that is, the reference processing characteristics and the processing characteristics of the adjustment processing apparatus match each other (process S32: YES). On the other hand, in a case where the processing threshold value of the adjustment processing apparatus is not included in the predetermined range (for example, reference processing threshold value ±5 μJ) including the reference processing threshold value, the controller 5 can determine that the reference processing threshold value and the processing threshold value of the adjustment processing apparatus do not match each other, that is, the reference processing characteristics and the processing characteristics of the adjustment processing apparatus do not match each other (process S32: NO).

From the result of the determination in process S32, in a case where the processing characteristics acquired in process S30 match the reference processing characteristics (process S32: YES), the controller 5 determines the setting value (the setting value that is temporarily determined in process S28) of the pulse width of the laser light L emitted to the functional element layer 12 in process S29 as a final setting value (process S33), and terminates the process.

On the other hand, from the result of the determination in process S32, in a case where the processing characteristics acquired in process S30 do not match the reference processing characteristics (process S32: NO), the controller 5 adjusts the setting value of the pulse width of the laser light L (process S34, adjustment process). Here, fine adjustment with a finer adjustment range is performed in comparison to the case of performing irradiation with the laser light L and imaging while changing the pulse width in process S26 to determine the temporal setting value of the pulse width. In process S26, an example of changing the pulse width with a pitch width of 10% is exemplified. Therefore, it is estimated that a value of a true pulse width capable of obtaining processing characteristics matching the reference processing characteristics exists in a range of ±10% from the temporal setting value. Accordingly, the adjustment range in process S34 can be set to 5% as an example.

Next, the controller 5 repeats process S29 to process S31 with the pulse width after fine adjustment. Then, the controller 5 performs determination in process S32 again. That is, the controller 5 repeats process S29 to process S32 until a pulse width leading to processing characteristics matching the reference processing characteristics can be obtained. As a result, the controller 5 executes an adjustment process of performing adjustment of the pulse width of the processing laser light L in correspondence with the processing characteristics, and particularly, in the adjustment process, on the basis of the reference data including the reference pulse width and the reference processing characteristics associated with the reference pulse width, in a case where the processing characteristics acquired in the characteristic acquisition process do not match the reference processing characteristics, the controller 5 adjusts the pulse width of the laser light L so that the processing characteristics match the reference processing characteristics.

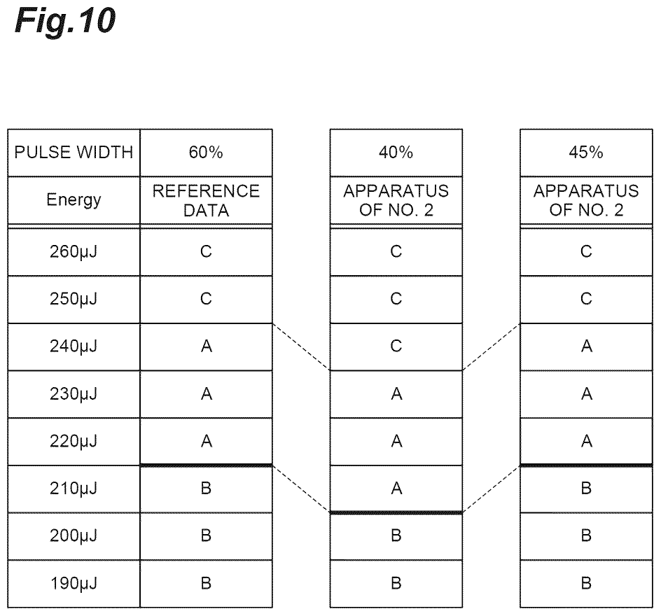

As illustrated in FIG. 10, even in a case where an initial temporal setting value of the pulse width is 40%, and there is a difference between the processing characteristics (processing threshold value) of the adjustment target processing apparatus (apparatus of No. 2) and the reference processing characteristics (reference processing threshold value) which are processing characteristics of the reference data, the processing characteristics (processing threshold value) of the adjustment target processing apparatus can be made to match the reference processing characteristics (reference processing threshold value) by adjusting the pulse width by 5% to set the pulse width to 45%.

As described above, in the laser processing apparatus 1 and the laser processing method according to this embodiment, laser processing of irradiating the substrate 10 with the laser light L and characteristic acquisition of acquiring processing characteristics of the substrate 10 by imaging the substrate 10 by using the observation transmission light L0 are performed. In addition, in a case where the acquired processing characteristics do not match the reference processing characteristics included in predetermined reference data, the pulse width of the laser light L is adjusted so that the processing characteristics match the reference processing characteristics. As a result, the pulse width of the laser light L is adjusted so that the processing characteristics match a predetermined reference. Accordingly, when the reference data is set to be common to a plurality of the laser processing apparatuses 1, a machine difference of the processing characteristics can be suppressed. Note that, examples of the processing characteristics include a formation state of the modified region 15A in the substrate 10, a formation state of the peeling portion 15B at the periphery of the modified region 15A, presence or absence of the damage 15C, and the like.

In addition, the laser processing apparatus 1 includes the pulse waveform sensor 41 that detects the laser light L to acquire the pulse waveform of the laser light L. The controller 5 executes the pulse width acquisition process of acquiring the setting value of the pulse width of the laser light L and the actual measurement value of the pulse width of the laser light L at the setting value by acquiring the pulse waveform by detecting the laser light L emitted from the processing light source 31 with the pulse waveform sensor 41 a plurality of times while changing the setting value. According to this, the controller 5 acquires a plurality of the actual measurement values respectively associated with a plurality of the setting values of the pulse width of the laser light L, and determines a setting value that becomes an actual measurement value closest to the reference pulse width among the plurality of actual measurement values as a temporal setting value on the basis of the reference data. Furthermore, in the processing process, the controller 5 sets the setting value of the pulse width of the laser light L as a temporal setting value. According to this, it is possible to limit an adjustment width when adjusting the pulse width of the laser light L so that the processing characteristics match the reference processing characteristics.

In addition, in the laser processing apparatus 1, the reference data includes a reference image that is an image of a reference target object irradiated with the laser light L as the reference processing characteristics. In the characteristic acquisition process, the controller 5 images the substrate 10 irradiated with the laser light L by using the observation transmission light L0 to acquire a processing image that is an image of the substrate 10 as processing characteristics. Then, in the adjustment process, in a case where the reference image and the processing image do not match each other through image processing, the controller 5 adjusts the pulse width of the laser light L so that the reference image and the processing image match each other. In this manner, a series of processes can be automated.

Here, the laser processing apparatus 1 may present information related to comparison between the reference data including the reference pulse width and the reference processing characteristics associated with the reference pulse width, and the processing characteristics acquired in the characteristic acquisition process without performing the adjustment process by the controller 5. In this case, a determination is made as to whether or not the processing characteristics match the reference processing characteristics on the basis of the presented information by a user, and in a case where the processing characteristics do not match the reference processing characteristics, the pulse width of the laser light L can be adjusted so that the processing characteristics match the reference processing characteristics. Accordingly, when the reference data is set to be common to a plurality of the laser processing apparatuses 1, a machine difference of the processing characteristics can be suppressed.

The above-described embodiment describes an aspect of the invention. Accordingly, the invention can be arbitrarily modified without limitation to the aspect. Subsequently, modification examples will be described.

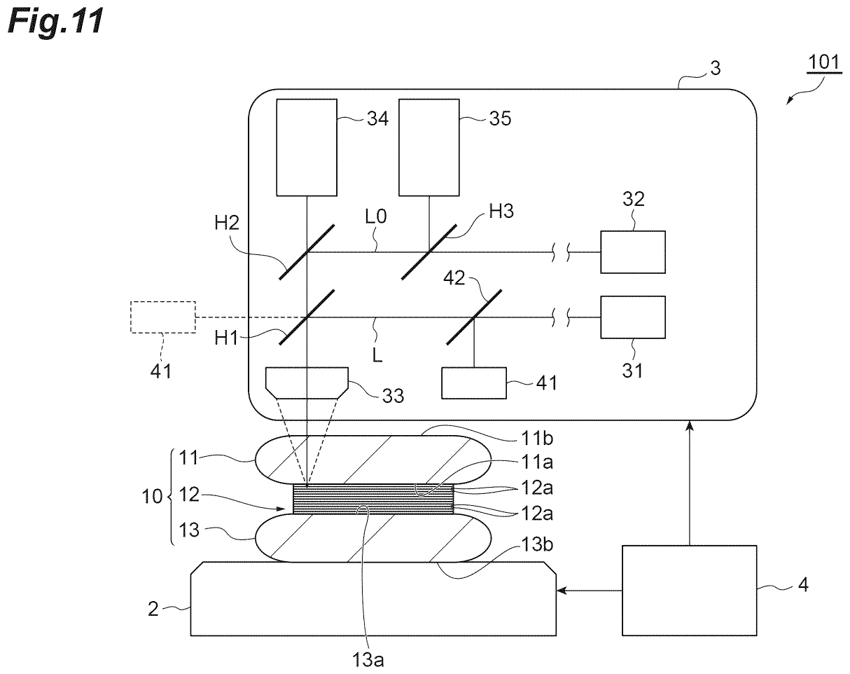

As illustrated in FIG. 11, a laser processing apparatus 101 according to a first modification example is different from the embodiment in that the laser processing head 3 further includes a second imaging element 35. The second imaging element 35 has further sensitivity to the laser light L, and further receives reflected light that is reflected in correspondence with irradiation with the laser light L. In this embodiment, the reflected light of the laser light L that is emitted to the substrate 10 and is reflected therefrom is detected by the second imaging element 35 through the condensing unit 33 and dichroic mirrors H1, H2, and H3. For example, the second imaging element 35 acquires an image related to a beam shape of the laser light L as an image. The second imaging element 35 outputs an imaging result to the controller 5. Note that, the first imaging element 34 of this embodiment may not have sensitivity to the laser light L. The display unit 6 may further display the imaging result of the second imaging element 35.

Even in this laser processing apparatus 101, a similar effect as in the laser processing apparatus 1 according to the embodiment can be exhibited. Furthermore, according to the laser processing apparatus 101, since the second imaging element 35 is further provided, it is possible to grasp a beam shape of the laser light L and the like by using the imaging result of the second imaging element 35.

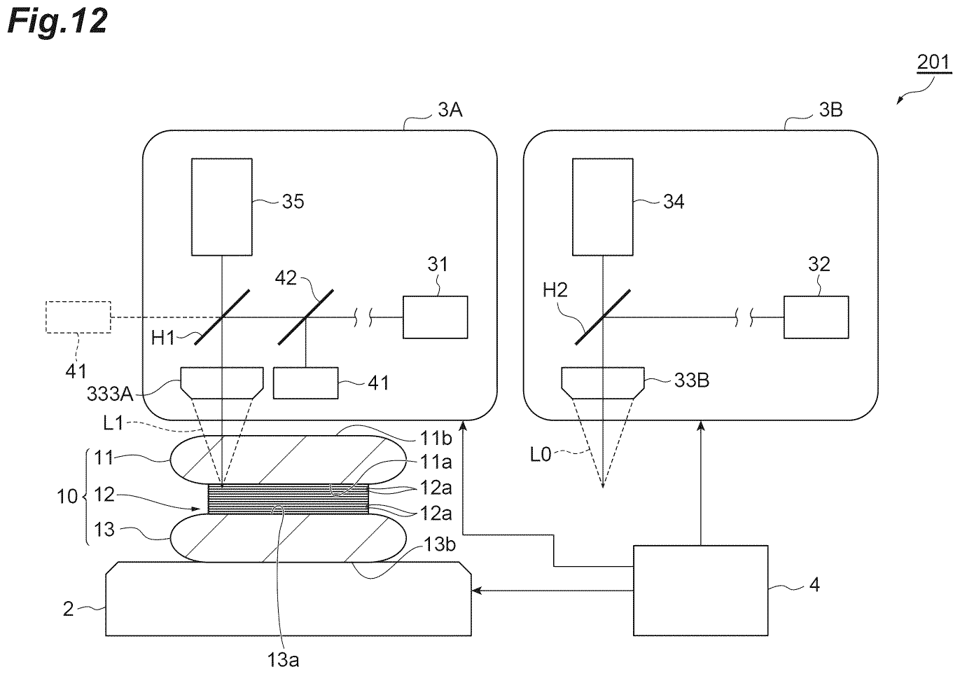

As illustrated in FIG. 12, a laser processing apparatus 201 according to a second modification example is different from the embodiment in that a laser processing head 3A and an observation head 3B are provided instead of the laser processing head 3 (refer to FIG. 1).

The laser processing head 3A includes the processing light source 31, a condensing unit 33A, and the second imaging element 35. The condensing unit 33A condenses the laser light L to the substrate 10 supported by the support portion 2. Here, the laser light L emitted from the processing light source 31 is reflected from the dichroic mirror H1 and is incident to the condensing unit 33A. The condensing unit 33A condenses the incident laser light L toward the substrate 10. For example, the condensing unit 33A is configured to include a lens unit consisting of a plurality of condensing lenses (however, may be a single lens). As the lens unit of the condensing unit 33A, a lens unit with low NA can be used. The second imaging element 35 has further sensitivity to the laser light L, and further receives reflected light that is reflected in correspondence with irradiation with the laser light L. For example, the second imaging element 35 acquires an image related to the beam shape of the laser light L as an image. The second imaging element 35 outputs an imaging result to the controller 5.

The observation head 3B includes an observation light source 32, a condensing unit 33B, and a first imaging element 34. The condensing unit 33B condenses the observation transmission light L0 toward the substrate 10 supported by the support portion 2. In this embodiment, the observation transmission light L0 emitted from the observation light source 32 is reflected from the dichroic mirror H2 and is incident to the condensing unit 33B. The condensing unit 33B condenses the incident observation transmission light L0 to the substrate 10. For example, the condensing unit 33B is configured to include a lens unit consisting of a plurality of condensing lenses (however, may be a single lens) as in the condensing unit 33A.

As described above, the laser processing head 3A and the observation head 3B are configured separately from each other, and emit the laser light L and the observation transmission light L0, respectively. The laser processing head 3A constitutes a processing irradiation unit that irradiates the substrate 10 with the laser light L from the rear surface 11b side, and the observation head 3B constitutes an observation irradiation unit that irradiates the substrate 10 with the observation transmission light L0 from the rear surface 11b. The laser processing head 3A may be provided with a spatial light modulator configured to modulate the laser light L, or may not be provided with the spatial light modulator. In addition, here, the movement mechanism 4 can independently move the laser processing head 3A and the observation head 3B in the Z-direction, or can integrally move the laser processing head 3A and the observation head 3B in the Z-direction.

Even in the laser processing apparatus 201, a similar effect as in the laser processing apparatus 1 according to the embodiment can be exhibited. Furthermore, according to the laser processing apparatus 201, the processing irradiation unit and the observation irradiation unit are configured separately as the laser processing head 3A and the observation head 3B, and the respective laser light L and observation transmission light L0 can be emitted from the laser processing head 3A and the observation head 3B along different axes.

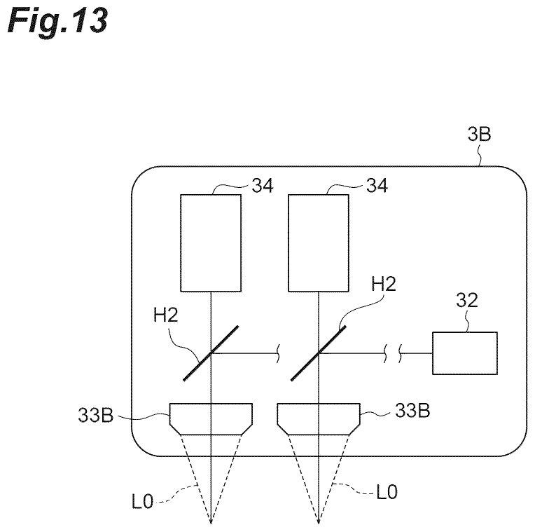

As illustrated in FIG. 13, the observation head 3B may include a plurality of the condensing units 33B and a plurality of the first imaging elements 34. Magnifications of respective lens units included in the plurality of condensing units 33B may be different from each other. In this case, the observation transmission light L0 may be condensed to the substrate 10 by using a condensing unit 33B including a lens unit with the highest magnification among the plurality of condensing units 33B.

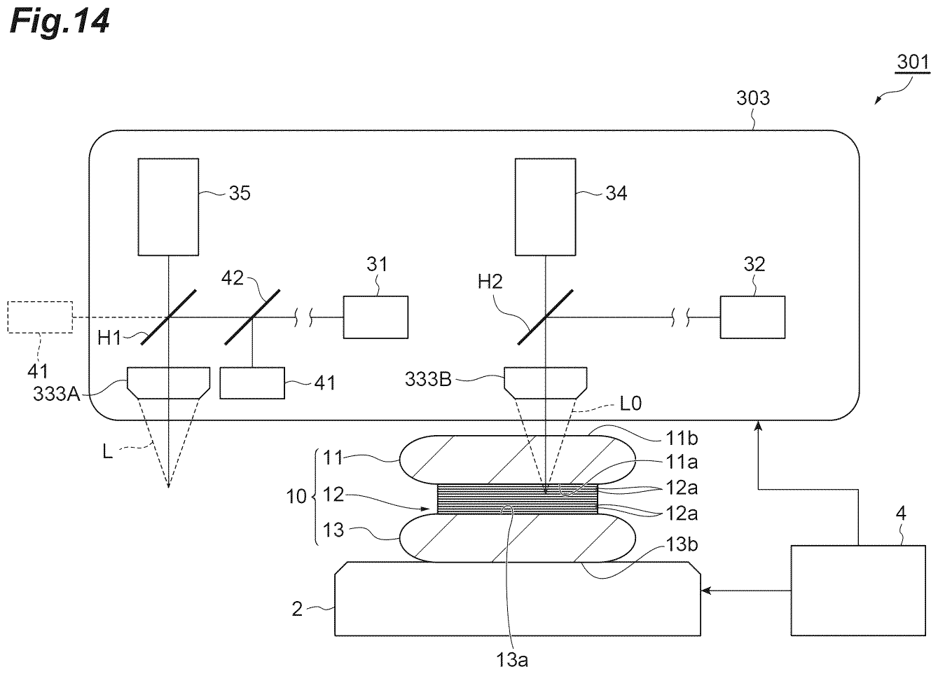

As illustrated in FIG. 14, a laser processing apparatus 301 according to a third modification example is different from the laser processing apparatus 1 according to the embodiment in that a laser processing head 303 is provided instead of the laser processing head 3 (refer to FIG. 1).

The laser processing head 303 includes the processing light source 31, a condensing unit 333A, the first imaging element 34, the observation light source 32, a condensing unit 333B, and the second imaging element 35. The condensing unit 333A condenses the laser light L toward the substrate 10 supported by the support portion 2. Here, the laser light L emitted from the processing light source 31 is reflected from the dichroic mirror H1 and is incident to the condensing unit 333A. The condensing unit 333A condenses the incident laser light L toward the substrate 10. For example, the condensing unit 333A is configured to include a lens unit consisting of a plurality of condensing lenses (however, may be a single lens). As the lens unit of the condensing unit 333A, a lens unit with low NA can be used.

The condensing unit 333B condenses the observation transmission light L0 toward the substrate 10 supported by the support portion 2. Here, the observation transmission light L0 emitted from the observation light source 32 is reflected from the dichroic mirror H2 and is incident to the condensing unit 333B. The condensing unit 333B condenses the incident observation transmission light L0 toward the substrate 10. For example, the condensing unit 333B is configured to include a lens unit consisting of a plurality of condensing lenses (however, may be a single lens) as in the condensing unit 333A. The second imaging element 35 has further sensitivity to the laser light L, and further receives reflected light that is reflected in correspondence with irradiation with the laser light L. For example, the second imaging element 35 acquires an image related to the beam shape of the laser light L as an image. The second imaging element 35 outputs an imaging result to the controller 5.

The laser processing head 303 emits the laser light L and the observation transmission light L0 along different axes. The laser processing head 303 constitutes the processing irradiation unit that irradiates the substrate 10 with the laser light L from the rear surface 11b side, and the observation irradiation unit that irradiates the substrate 10 with the observation transmission light L0 from the rear surface 11b. The laser processing head 303 may be provided with a spatial light modulator configured to modulate the laser light L, or may not be provided with the spatial light modulator.

Even in the laser processing apparatus 301, a similar effect as in the laser processing apparatus 1 according to the embodiment can be exhibited. In addition, according to the laser processing apparatus 301, the processing irradiation unit and the observation irradiation unit are configured integrally as the laser processing head 303, and the laser light L and the observation transmission light L0 can be emitted from the laser processing head 303 along different axes.

Here, the embodiment exemplifies a configuration in which the virtual plane M1 is set to extend over the entire region of the functional element layer 12 when viewed from the Z-direction, and the modified region is formed to extend along the entire region of the functional element layer 12 (entire surface interlayer peeling processing), but there is no limitation to the configuration. A virtual plane may be set to extend over a partial region of the functional element layer 12 when viewed from the Z-direction, and the modified region may be formed to extend over the partial region of the functional element layer 12. In this case, the substrate 10 (the functional element layer 12) can be partially peeled off by using the modified region formed at the partial region of the functional element layer 12.

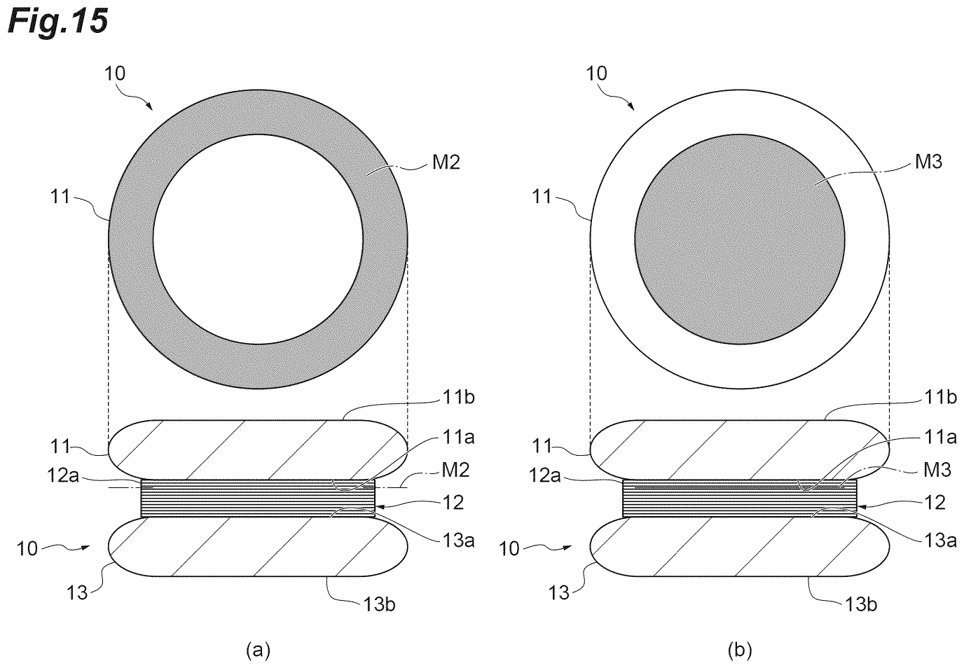

For example, as illustrated in FIG. 15(a), when viewed from the Z-direction, a virtual plane M2 that extends to an outer peripheral portion of the functional element layer 12 may be set, and the modified region may be formed to extend to the outer peripheral portion of the functional element layer 12 (outer peripheral portion interlayer peeling processing). In addition, for example, as illustrated in FIG. 15(b), when viewed from the Z-direction, a virtual plane M3 that extends to an inner peripheral portion of the functional element layer 12 may be set, and the modified region may be formed to extend to the inner peripheral portion of the functional element layer 12 (inner peripheral portion interlayer peeling processing).

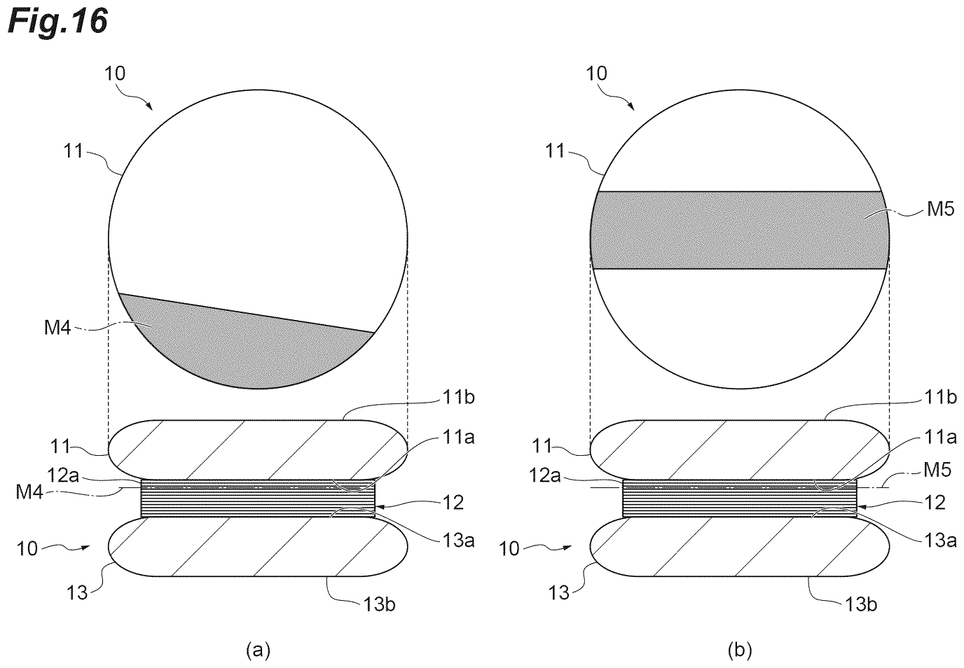

In addition, for example, as illustrated in FIG. 16(a), when viewed from the Z-direction, an arc-shaped virtual plane M4 may be set, and the modified region may be formed to extend to a partial portion of the arch in the functional element layer 12 (partial interlayer peeling processing). In addition, for example, as illustrated in FIG. 16(b), when viewed from the Z-direction, a virtual plane M5 may be set to extend over a partial portion sandwiched between a pair of arches in a circle, and the modified region may be formed to extend to the partial portion in the functional element layer 12 (partial interlayer peeling processing).

In the embodiment, the kind of the substrate 10, the shape of the substrate 10, the size of the substrate 10, the number and direction of crystal orientations in the substrate 10, a surface direction of a main surface of the substrate 10 are not particularly limited. In the embodiment, the substrate 10 may be formed from a crystal material having a crystal structure, or may be formed from an amorphous material having an amorphous structure instead of or in addition to the crystal material. The crystal material may be either an anisotropic crystal or an isotropic crystal. For example, the substrate 10 may include a substrate formed from at least any of gallium nitride (GaN), silicon (Si), silicon carbide (SiC), LiTaO3, diamond, GaOx, sapphire (Al2O3), gallium arsenide, indium phosphide, glass, and alkali-free glass.

In the embodiment, the modified region may be, for example, a crystal region, a recrystallization region, or a gettering region formed inside the substrate 10. The crystal region is a region retaining a structure of the substrate 10 before processing. The recrystallization region is a region that evaporates, turns into plasma, or is melted at once, and is solidified as a single crystal or a polycrystal when being resolidified. The gettering region is a region exhibiting a gettering effect of trapping impurities such as a heavy metal, and may be formed continuously or intermittently. The embodiment may be applied to processing such as ablation.

Furthermore, the embodiment exemplifies a case where the controller 5 performs comparison between a pulse width of the laser light L in the adjustment target processing apparatus and the reference pulse width, and a determination as to whether or not a processing image indicating processing characteristics of the adjustment target processing apparatus and a reference image indicating processing characteristics of the reference processing apparatus match each other, and the controller 5 adjusts the pulse width of the laser light in a case where the processing image and the reference image do not match each other. However, processes related to the comparison, the determination, and the adjustment are not limited to a case of being automatically performed by the controller 5.

That is, the controller 5 may present a user with information relating to the comparison and the determination, and may receive an input in correspondence with results of the comparison and the determination by the user. More specifically, in the adjustment process, the controller 5 may cause the display unit 6 to display the reference image and the processing image to be presented to the user, and the pulse width may be adjusted so that the pulse width of the laser light L becomes a user's input value received by the display unit 6.

Similarly, the controller 5 may cause the display unit 6 to display a pulse waveform that becomes the basis of calculation of the reference pulse width, and a pulse waveform of the laser light L in the adjustment target processing apparatus to be presented to the user, and may determine a pulse width value that is a user's input received by the display unit 6 as a temporal setting value. In these cases, a processing load on the controller 5 is reduced.

In addition, in the examples, a case where a pulse waveform of the laser light L is acquired by using the pulse waveform sensor 41, and an actual measurement value of a pulse width of the laser light L is acquired on the basis of the pulse waveform has been exemplified. However, acquisition of the actual measurement value of the pulse width is not essential. For example, in the adjustment process, the controller 5 may not acquire the actual measurement value of the pulse width of the laser light L, and in a case where the processing characteristics acquired in the characteristic acquisition process do not match the reference processing characteristics, the controller 5 may adjust the pulse width of the laser light L so that the processing characteristics match the reference processing characteristics on the basis of comparison of the processing characteristics.

Furthermore, in the embodiment, the substrate 10 includes the first substrate 11 and the second substrate 13, but there is no limitation to the configuration. For example, the substrate 10 may not include the second substrate 13.

Various materials and shapes are applicable to the respective configurations in the embodiment and the modification examples without limitation to the above-described materials and shapes. In addition, the respective configurations in the above-described embodiment or modification examples are arbitrarily applicable to respective configurations of other embodiments or modification examples.

### INDUSTRIAL APPLICABILITY

There are provided a laser processing apparatus, a laser processing method, and a data generation method which are capable of suppressing a machine difference in processing characteristics.

### REFERENCE SIGNS LIST

1: laser processing apparatus, 2: support portion, 3: laser processing head (processing irradiation unit, observation irradiation unit), 5: controller, 6: display unit (display unit, input reception unit), 10: substrate, 11: first substrate, 11a: front surface (first main surface), 11b: rear surface (second main surface), 12: functional element layer, 13: second substrate, L: laser light (processing laser light), L0: observation transmission light.

1. A laser processing apparatus configured to irradiate a substrate including a first main surface and a second main surface opposite to the first main surface with processing laser light, comprising:
a processing irradiation unit configured to irradiate the substrate with the processing laser light from the second main surface side;
an observation irradiation unit configured to irradiate the substrate with observation transmission light from the second main surface side;
an imaging element configured to image the observation transmission light from the substrate; and
a controller configured to execute a processing process of irradiating the substrate with the processing laser light by controlling the processing irradiation unit, a characteristic acquisition process of irradiating the substrate with the observation transmission light, imaging the observation transmission light from the substrate, and acquiring processing characteristics on the substrate in the processing process by controlling the observation irradiation unit and the imaging element, and an adjustment process of adjusting a pulse width of the processing laser light in correspondence with the processing characteristics,
wherein in the adjustment process, on the basis of reference data including a reference pulse width and reference processing characteristics associated with the reference pulse width, in a case where the processing characteristics acquired in the characteristic acquisition process do not match the reference processing characteristics, the controller adjusts the pulse width of the processing laser light so that the processing characteristics match the reference processing characteristics.

2. The laser processing apparatus according to claim 1, further comprising:
a pulse waveform sensor configured to acquire a pulse waveform of the processing laser light by detecting the processing laser light,
wherein the controller executes pulse width acquisition process of acquiring a setting value of the pulse width of the processing laser light and an actual measurement value of the pulse width of the processing laser light at the setting value by acquiring the pulse waveform by detecting the processing laser light emitted from the processing irradiation unit using the pulse waveform sensor a plurality of times while changing the setting value in order to acquire a plurality of the actual measurement values respectively associated with a plurality of the setting values of the pulse width of the processing laser light, and determines the setting value that becomes an actual measurement value closest to the reference pulse width among the plurality of the actual measurement values on the basis of the reference data as a temporary setting value, and
in the processing process, the controller sets the setting value of the pulse width of the processing laser light to the temporary setting value.

3. The laser processing apparatus according to claim 1,
wherein the reference data includes a reference image that is an image of a reference target object irradiated with the processing laser light as the reference processing characteristics,
in the characteristic acquisition process, the controller images the substrate irradiated with the processing laser light by using the observation transmission light to acquire a processing image that is an image of the substrate as the processing characteristics, and
in the adjustment process, in a case where the reference image and the processing image do not match each other through image processing, the controller adjusts the pulse width of the processing laser light so that the reference image and the processing image match each other.

4. The laser processing apparatus according to claim 1, further comprising:
a display unit configured to display an image; and
an input reception unit configured to receive an input,
wherein the reference data includes a reference image that is an image of a reference target object irradiated with the processing laser light as the reference processing characteristics,
in the characteristic acquisition process, the controller images the substrate irradiated with the processing laser light by using the observation transmission light to acquire a processing image that is an image of the substrate as the processing characteristics, and
in the adjustment process, the controller causes the display unit to display the reference image and the processing image, and adjusts the pulse width so that the pulse width of the processing laser light becomes a value that the input reception unit receives an input.

5. A laser processing apparatus configured to irradiate a substrate including a first main surface and a second main surface opposite to the first main surface with processing laser light, comprising:
a processing irradiation unit configured to irradiate the substrate with the processing laser light from the second main surface side;
an observation irradiation unit configured to irradiate the substrate with observation transmission light from the second main surface side;
an imaging element configured to image the observation transmission light from the substrate; and
a controller configured to execute a processing process of irradiating the substrate with the processing laser light by controlling the processing irradiation unit, and a characteristic acquisition process of irradiating the substrate with the observation transmission light, imaging the observation transmission light from the substrate, and acquiring processing characteristics on the substrate in the processing process by controlling the observation irradiation unit and the imaging element,
wherein the controller presents information relating to comparison between reference data including a reference pulse width and reference processing characteristics associated with the reference pulse width, and the processing characteristics acquired in the characteristic acquisition process.

6. A laser processing method of irradiating a substrate including a first main surface and a second main surface opposite to the first main surface with processing laser light, comprising:
a processing process of irradiating the substrate with the processing laser light from the second main surface side;
a characteristic acquisition process of irradiating the substrate with observation transmission light from the second main surface side, imaging the observation transmission light from the substrate, and acquiring processing characteristics on the substrate in the processing process; and
an adjustment process of adjusting a pulse width of the processing laser light in correspondence with the processing characteristics,
wherein in the adjustment process, on the basis of reference data including a reference pulse width and reference processing characteristics associated with the reference pulse width, in a case where the processing characteristics acquired in the characteristic acquisition process do not match the reference processing characteristics, the pulse width of the processing laser light is adjusted so that the processing characteristics match the reference processing characteristics.

7. A data generation method of generating reference data that becomes an adjustment reference of a pulse width of processing laser light in laser processing of irradiating a substrate with the processing laser light, including:
a reference processing process of irradiating a reference target object with the processing laser light;
a reference characteristic acquisition process of irradiating the reference target object with observation transmission light and imaging the observation transmission light from the reference target object to acquire reference processing characteristics as processing characteristics on the reference target object in the reference processing process; and
a generation process of associating the reference processing characteristics obtained in the reference characteristic acquisition process with a pulse width of the processing laser light when obtaining the reference processing characteristics as a reference pulse width to generate the reference data including the reference processing characteristics and the reference pulse width associated with the reference processing characteristics.
